(19) United States
(12) Patent Application Publication
(10) Pub. No.: US 2017/0367195 A1
(43) Pub. Date: Dec. 21, 2017

(54) PRINTED CIRCUIT BOARD AND MANUFACTURING METHOD THEREOF

(71) Applicant: SEIKO EPSON CORPORATION, Tokyo (JP)

(72) Inventors: Yoshikazu TAKAHASHI, Chino-shi (JP); Masanobu SHOJI, Tsuruoka-shi (JP)

(73) Assignee: SEIKO EPSON CORPORATION, Tokyo (JP)

(21) Appl. No.: 15/601,205

(22) Filed: May 22, 2017

(30) Foreign Application Priority Data
Jun. 15, 2016 (JP) 2016-118528

(51) Int. Cl. H05K 3/34; H05K 3/00; H05K 3/22; H05K 3/40

(52) U.S. Cl. CPC H05K 3/3405; H05K 3/403; H05K 3/3468; H05K 3/0097; H05K 3/22; H05K 3/3463

(57) ABSTRACT

The manufacturing method includes (a) preparing first printed circuit board and second printed circuit board, the first printed circuit board being provided with a plurality of first terminals, the second printed circuit board being provided with a plurality of second terminals, and the first terminals or the second terminals being coated with solders; and (b) connecting the first terminals and the second terminals, respectively, via respective solders by performing thermocompression on connecting portions of the first printed circuit board and the second printed circuit board. Each second terminal includes a first end portion and a second end portion in a long axis direction, and in the step (b), pressure is applied to each second terminal such that the height of each of the first end portion and second end portion is larger than the height in another portion of the second terminal.

### BACKGROUND

### 1. Technical Field

The present invention relates to printed circuit boards, manufacturing methods thereof, and the like.

### 2. Related Art

A composite printed circuit board (hereinafter also referred to as “composite module”) is manufactured by electrically connecting a plurality of terminals provided in a flexible printed circuit board to a plurality of terminals provided in a rigid printed circuit board, respectively, for example. Here, two boards are bonded by thermocompression using a thermocompression tool in a state in which the terminals of one printed circuit board face the corresponding terminals of the other printed circuit board via solders, and thus the corresponding terminals of the two printed circuit boards are joined by the solders.

However, in recent years, terminals of a printed circuit board tend to be arranged at a fine pitch in order to achieve high integration, and the distance between terminals decreases. Also, in the case where solders are applied to terminals by screen printing or the like, it is difficult to strictly control the thickness of each solder, and the thicknesses of the solders vary. As a result, a solder bridge problem in which, when two boards are bonded by thermocompression, excess molten solder spreads out and short-circuits adjacent terminals becomes more serious.

A solder bridge is formed according to the following reason. Because a substrate 3 exists above lead portions (terminals) 5, as shown in FIGS. 1 to 3 in JP-A-2005-26561, when a molten solder is pressed between an electronic apparatus 2 and the substrate 3, the molten solder can only escape in the left and right directions in FIG. 3. These directions are directions in which the lead portions 5 and electrodes 6 are respectively arranged.

Also, the applied amounts of solders 8 and 9 applied to the lead portions 5 and the electrodes 6 vary to some degree. Therefore, if the applied amounts of solders 8 and 9 applied to the lead portions 5 and the electrodes 6 are larger than a prescribed amount, even by a small amount, bridges are formed between adjacent pairs of the lead portion 5 and the electrode 6, as shown in FIG. 3 in JP-A-2005-26561.

It is conceivable to solve the solder bridge problem by forming slits 18 between adjacent lead portions 15, as shown in FIG. 4 in JP-A-2005-26561. However, in this case, the lead portions 15 are in a state of protruding from a substrate 13 in a cantilever form, and the lead portions 15 cannot be mechanically protected or electrically insulated by the substrate 13.

### SUMMARY

Some aspects of the invention relate to providing a manufacturing method of a printed circuit board in which formation of a solder bridge that is caused by excess molten solder spreading out and short-circuits adjacent terminals can be suppressed, when a plurality of terminals of a first printed circuit board are electrically connected to a plurality of terminals of a second printed circuit board, respectively, via respective solders.

Also, some aspects of the invention relate to a printed circuit board that is configured by electrically connecting a plurality of terminals of a first printed circuit board to a plurality of terminals of a second printed circuit board, respectively, via respective solders, wherein, even if a force is applied between the second printed circuit board and the first printed circuit board in a direction such that the second printed circuit board is torn off from the first printed circuit board, the printed circuit board is hardly broken.

A manufacturing method of a printed circuit board according to a first aspect of the invention includes: (a) preparing first printed circuit board and second printed circuit board, the first printed circuit board being provided with a plurality of first terminals, the second printed circuit board being provided with a plurality of second terminals, and at least one of the plurality of first terminals and the plurality of second terminals being coated with respective solders, and (b) electrically connecting the plurality of first terminals to the plurality of second terminals, respectively, via the respective solder by heating connecting portions of the first printed circuit board and the second printed circuit board to a temperature that is greater than or equal to a melting point of the solder and applying pressure to the connecting portions. The plurality of second terminals are arranged along a short axis direction of the second terminals. Each of the plurality of second terminals includes a first end portion and a second end portion in a long axis direction of the second terminal. In the step (b), pressure is applied to each second terminal such that the height of each of the first end portion and second end portion is larger than the height in another portion of the second terminal.

According to the first aspect of the invention, the solder that is applied between the other portion of the second terminal and the first terminal is caused to escape in directions toward the first end portion and the second end portion of the second terminal, and as a result, the formation of a solder bridge that is caused by excess molten solder spreading out and short-circuits adjacent terminals can be suppressed.

Here, the step (b) may include bringing a thermocompression tool into contact with a predetermined region, of the second printed circuit board, that is located between the first end portions and the second end portions of the plurality of second terminals in plan view. Accordingly, the first end portion and the second end portion that are provided in a region, of the second printed circuit board, that does not come into contact with the thermocompression tool separate from the rigid board, and thereby a solder escape structure can be formed.

In that described above, the first printed circuit board may be a rigid board, and the second printed circuit board may be a flexible board. In this case, the shape of the flexible board can be easily changed by bringing the thermocompression tool into contact with the flexible board, and therefore, the solder escape structure can be easily formed.

A printed circuit board according to a second aspect of the invention includes: a first printed circuit board provided with a plurality of first terminals; a second printed circuit board provided with a plurality of second terminals; and solders that electrically connect the plurality of first terminals to the plurality of second terminals, respectively. The plurality of second terminals are arranged along a short axis direction of the second terminals. Each of the plurality of second terminals includes a first end portion and a second end portion in a long axis direction of the second terminal. The height of each of the first end portion and second end portion is larger than the height in another portion of each second terminal.

According to the second aspect of the invention, each second terminal of the second printed circuit board is connected to the corresponding first terminal of the first printed circuit board such that the second terminal has, at least in the first end portion and second end portion, tilt angles relative to the first printed circuit board. Accordingly, even if a force is applied between the second printed circuit board and the first printed circuit board in a direction such that the second printed circuit board is torn off from the first printed circuit board, the concentration of stress at the first end portion and second end portion of each second terminal is mitigated, and the printed circuit board is unlikely to break.

Here, the plurality of first terminals and the plurality of second terminals are arranged at a pitch that is less than or equal to 0.5 mm. According to the second aspect of the invention, as a result of suppressing the formation of a solder bridge, the distance between adjacent terminals is reduced and the terminals can be arranged at a fine pitch, and high integration of the printed circuit board can be achieved.

### BRIEF DESCRIPTION OF THE DRAWINGS

The invention will be described with reference to the accompanying drawings, wherein like numbers reference like elements.

FIG. 1 is a cross-sectional view for describing a first step of a manufacturing method of a printed circuit board.

FIG. 2 is a cross-sectional view for describing a second step of the manufacturing method of a printed circuit board.

FIG. 3 is a plan view of a rigid board shown in FIG. 1.

FIG. 4 is a bottom view of a flexible board shown in FIG. 1.

FIG. 5 is a plan view illustrating a state in which the flexible board is arranged on the rigid board.

FIG. 6 is a plan view illustrating a state in which the flexible board is bonded to the rigid board by thermocompression.

FIG. 7 is a plan view illustrating an example of a pitch of terminals in a printed circuit board.

### DESCRIPTION OF EXEMPLARY EMBODIMENTS

Hereinafter, an embodiment of the invention will be described in detail with reference to the drawings. The same constituent elements are given the same reference numerals, and redundant descriptions are omitted.

### Manufacturing Method of Printed Circuit Board

A first printed circuit board and a second printed circuit board are used in order to manufacture a composite printed circuit board (composite module) according to one embodiment of the invention. In the following, a case where the first printed circuit board is a rigid board and the second printed circuit board is a flexible board will be described, as an example.

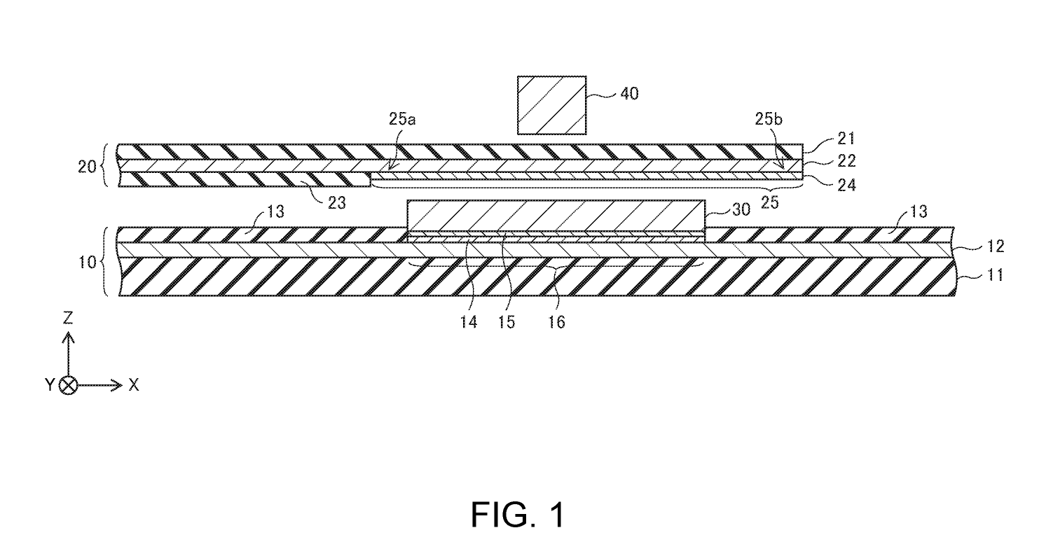

FIG. 1 is a cross-sectional view for describing a first step of a manufacturing method of a printed circuit board according to one embodiment of the invention. In the first step, a rigid board 10 and a flexible board 20 are prepared. As shown in FIG. 1, the rigid board 10 includes a substrate 11 and conductive patterns 12 that are selectively arranged on the substrate 11. For example, the substrate 11 is made of an insulating material such as paper phenol or glass epoxy, and the conductive pattern 12 is made of a conductive material such as copper (Cu).

First regions (left and right regions in the diagram) of a principal surface (upper surface in the diagram) of the rigid board 10 are covered by solder resists 13. Nickel (Ni) plating films 14 and gold (Au) plating films 15 may be arranged on the conductive patterns 12 in a second region (central region in the diagram), of the principal surface of the rigid board 10, that are not covered by the solder resist 13. The conductive patterns 12, the nickel plating films 14, and the gold plating films 15 in the second region constitute a plurality of first terminals (lands) 16 provided in the rigid board 10.

The plurality of first terminals 16 whose long axis direction is in a X-axis direction are arranged along a short axis direction (Y-axis direction) of the first terminals 16 in the rigid board 10. Furthermore, electronic components such as a semiconductor integrated circuit (IC), a transistor, a resistor, a capacitor, and an inductor may be mounted on the rigid board 10.

Also, the flexible board 20 includes a flexible tape 21 and conductive patterns 22. For example, the flexible tape 21 is made of an insulating resin such as polyimide or polyester, and the conductive patterns 22 are made of a conductive material such as copper (Cu).

A first region (left side region in the diagram) of a principal surface (lower surface in the diagram) of the flexible board 20 is covered by a solder resist 23. Gold (Au) plating films 24 may be arranged on the conductive patterns 22 in a second region (right side region in the diagram) of the principal surface of the flexible board 20 that is not covered by the solder resist 23. The conductive patterns 22 and the gold plating films 24 in the second region constitute a plurality of second terminals (lands) 25 provided in the flexible board 20.

The plurality of second terminals 25 whose long axis direction is the X-axis direction are arranged along a short axis direction (Y-axis direction) of the second terminals 25 in the flexible board 20. Also, each of the plurality of second terminals 25 includes a first end portion 25a and a second end portion 25b in the long axis direction of the second terminal 25. Furthermore, the flexible board 20 may be electrically connected to another electronic component, another printed circuit board, or the like via a plurality of third terminals provided in a third region.

At least one of the first terminals 16 of the rigid board 10 and the second terminals 25 of the flexible board 20 are coated with solders 30 that include tin (Sn). In the example shown in FIG. 1, the first terminals 16 of the rigid board 10 are coated with paste solders 30 through screen printing or the like, for example.

The rigid board 10 is placed on a flat surface of a plate (not shown) such that the first terminals 16 on which the solders 30 are applied face upward. Also, the flexible board 20 is positioned relative to the rigid board 10 such that the plurality of first terminals 16 of the rigid board 10 respectively face the plurality of second terminals 25 of the flexible board 20 via respective solders 30. Furthermore, a thermocompression tool 40 serving as a heating and pressurization member is arranged in order to bond the flexible board 20 to the rigid board 10 by using thermocompression.

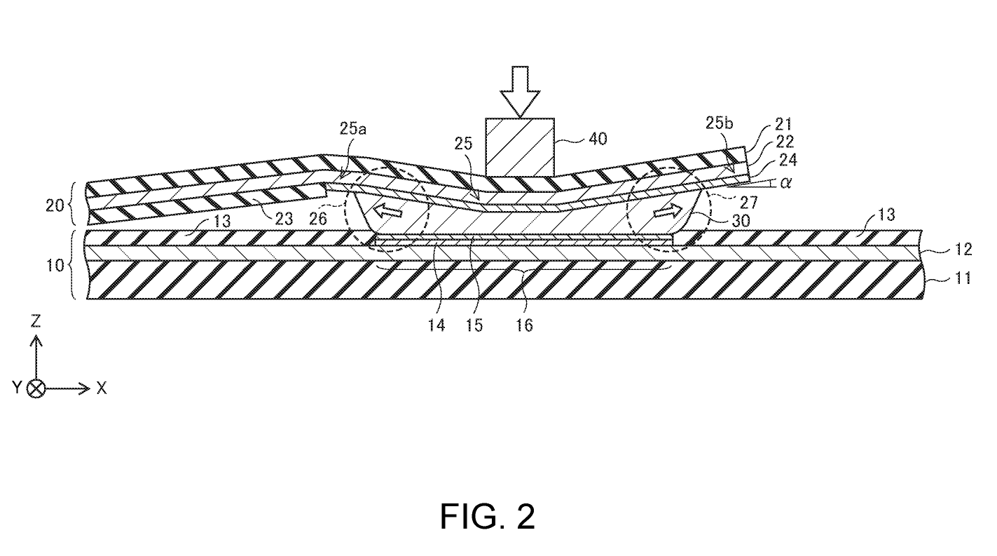

FIG. 2 is a cross-sectional view for describing a second step of the manufacturing method of a printed circuit board according to one embodiment of the invention. In the second step, by causing the thermocompression tool 40 to apply heat to connecting portions of the rigid board 10 and the flexible board 20 to a temperature that is greater than or equal to the melting point of the solders 30 and apply pressure to the connecting portions, the plurality of first terminals 16 of the rigid board 10 are electrically connected to the plurality of second terminals 25 of the flexible board 20, respectively, via the respective solders 30.

Here, as shown in FIG. 2, pressure is applied to each second terminal 25 by the thermocompression tool 40 such that the heights of the first end portion 25a and the second end portion 25b of the second terminal 25 of the flexible board 20 are larger than the height of the other portion (central portion) of the second terminal 25 with reference to the principal surface of the rigid board 10. That is, pressure is applied to each second terminal 25 by the thermocompression tool 40 such that the distance between each of the first end portion 25a and the second end portion 25b of the second terminal 25 of the flexible board 20 and the rigid board 10 is larger than the distance between the other portion (central portion) of the second terminal 25 and the rigid board 10.

According to the present embodiment, the solder 30 that is applied between the other portion (central portion) of each second terminal 25 and the corresponding first terminal 16 is caused to escape in a direction toward the first end portion 25a of the second terminal 25 and in a direction toward the second end portion 25b (arrow directions in the diagram), and as a result, the formation of a solder bridge that is caused by excess molten solder spreading out in the Y-axis direction and short-circuits adjacent terminals can be suppressed.

In order to do this, in the second step, the thermocompression tool 40 may be brought into contact with a predetermined region, of the flexible board 20, that is located between the first end portions 25a and the second end portions 25b of the plurality of second terminals 25 in plan view. Note that, in the present application, “in plan view” refers to viewing portions in a direction vertical to the bottom surface of the rigid board 10 in a see-through manner.

Accordingly, the first end portions 25a and the second end portions 25b that are provided in a region, of the flexible board 20, that does not come into contact with the thermocompression tool 40 move away from the rigid board 10, and solder escape structures 26 and 27 can be formed. In order to form the solder escape structures 26 and 27 having a sufficient size, the length of the thermocompression tool 40 in the X-axis direction is desirably a half or less of the length of the solders 30 applied on the first terminals 16 of the rigid board 10 in the X-axis direction shown in FIG. 1, and is further desirably a third or less thereof.

In the case where the first printed circuit board is the rigid board 10 and the second printed circuit board is the flexible board 20, as in the present embodiment, the shape of the flexible board 20 can be easily changed by bringing the thermocompression tool 40 into contact with the flexible board 20, and therefore, the solder escape structures 26 and 27 can be easily formed.

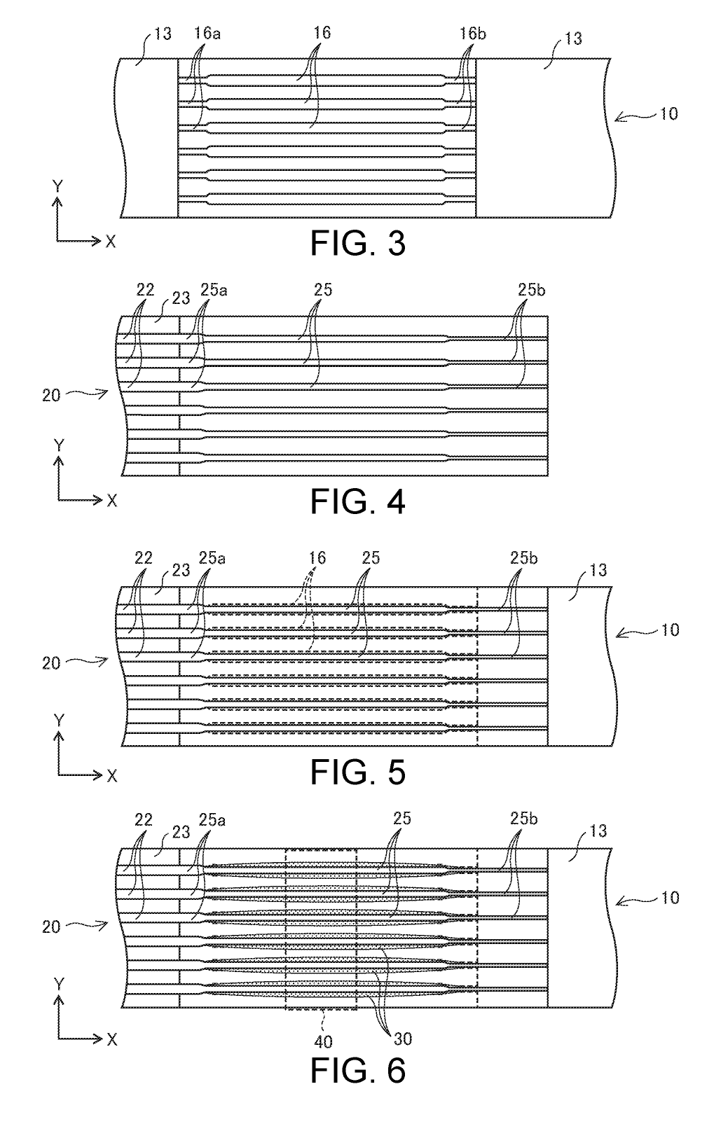

FIG. 3 is a plan view of the rigid board shown in FIG. 1. As shown in FIG. 3, the first regions (left and right regions in the diagram) of the principal surface of the rigid board 10 are covered by the solder resists 13. In the second region (central region in the diagram), of the principal surface of the rigid board 10, that is not covered by the solder resist 13, the plurality of first terminals 16 whose long axis direction is the X-axis direction are arranged along the short axis direction (Y-axis direction) of the first terminals 16. Also, each of the plurality of first terminals 16 includes the first end portion 16a and the second end portion 16b in the long axis direction of the first terminal 16.

The conductive patterns 12 (FIG. 1) that constitute the first terminals 16 extend under the solder resists 13. The width of the central portion of each first terminal 16 is set to be larger than the width of each of the first end portion 16a and the second end portion 16b of the first terminal 16. The first terminals 16 of the rigid board 10 are coated with the solders 30 (FIG. 1).

FIG. 4 is a bottom view of the flexible board shown in FIG. 1. In the example shown in FIG. 4, the flexible tape 21 (FIG. 1) is translucent, and the conductive patterns 22 and the solder resist 23 that are seen through the flexible tape 21 are shown. As shown in FIG. 4, the first region (left side region in the diagram), of the principal surface of the flexible board 20, is covered by the solder resist 23. In the second region (right side region in the diagram), of the principal surface of the flexible board 20, that is not covered by the solder resist 23, the plurality of second terminals 25 whose long axis direction is the X-axis direction are arranged in the short axis direction (Y-axis direction) of the second terminals 25. Also, each of the plurality of second terminals 25 includes the first end portion 25a and the second end portion 25b in the long axis direction of the second terminal 25.

In the example shown in FIG. 4, the width of each conductive pattern 22 that extends under the solder resist 23 is set to be large, and therefore, the width of the first end portion 25a of the second terminal 25 is larger than the width of the central portion of the second terminal 25. On the other hand, the width of the second end portion 25b of each second terminal 25 is smaller than the width of the central portion of the second terminal 25.

FIG. 5 is a plan view illustrating a state in which the flexible board is arranged on the rigid board. As shown in FIG. 5, the flexible board 20 is positioned relative to the rigid board 10 such that the plurality of first terminals 16 of the rigid board 10 respectively face the plurality of second terminals 25 of the flexible board 20 via respective solders 30 (FIG. 1).

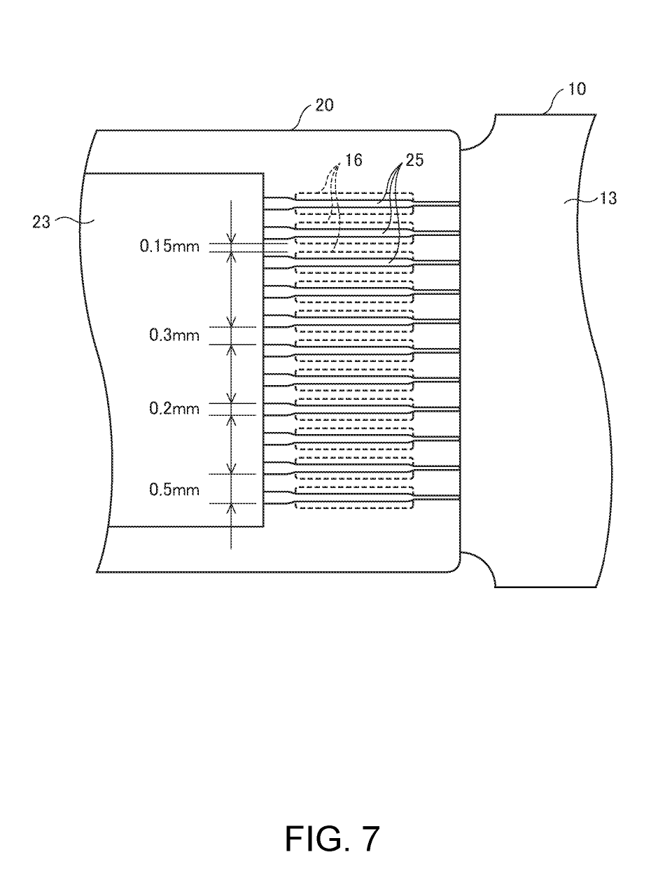

FIG. 6 is a plan view illustrating a state in which the flexible board is bonded to the rigid board by thermocompression. In FIG. 6, the outline of the thermocompression tool 40 is shown by broken lines, and the solders 30 that spread out from the plurality of second terminals 25 of the flexible board 20 are shown by dots. In this way, pressure is applied to the central portion of the second terminal 25 by the thermocompression tool 40, and the solders 30 are caused to escape from the central portions of the second terminals 25 toward both end portions of the respective second terminals 25, and as a result, the formation of a solder bridge that is caused by excess molten solder spreading out in the Y-axis direction and short-circuits adjacent terminals can be suppressed.

### Printed Circuit Board

A composite printed circuit board (composite module), as shown in FIGS. 2 and 6, is manufactured with the manufacturing method described above. The printed circuit board according to one embodiment of the invention includes the rigid board 10 in which the plurality of first terminals 16 are provided, the flexible board 20 in which the plurality of second terminals 25 are provided, and the solders 30 that electrically connect the plurality of first terminals 16 to the plurality of second terminals 25, respectively.

In the flexible board 20, the plurality of second terminals 25 are arranged along the short axis direction (Y-axis direction) of the second terminals 25. Also, each of the plurality of second terminals 25 includes the first end portion 25a and the second end portion 25b in the long axis direction (X-axis direction) of the second terminal 25. Here, the heights of the first end portion 25a and the second end portion 25b of each second terminal 25 of the flexible board 20 are larger than the height of the other portion (central portion) of the second terminal 25 with reference to the principal surface of the rigid board 10. That is, the distance between each of the first end portion 25a and the second end portion 25b of each second terminal 25 of the flexible board 20 and the rigid board 10 is larger than the distance between the other portion (central portion) of the second terminal 25 and the rigid board 10.

According to the present embodiment, each second terminal 25 of the flexible board 20 is connected to the corresponding first terminal 16 of the rigid board 10 such that the second terminal 25 has, at least in the first end portion 25a and the second end portion 25b, tilt angles α (α≠0°) relative to the rigid board 10. Accordingly, even if a force is applied between the flexible board 20 and the rigid board 10 in a direction such that the flexible board 20 is torn off from the rigid board 10 (up-down direction, for example), the concentration of stress at the first end portion 25a and the second end portion 25b of each second terminal 25 is mitigated, and the printed circuit board (composite module) is unlikely to break.

FIG. 7 is a plan view illustrating an example of a pitch of the terminals in the printed circuit board according to one embodiment of the invention. In the example shown in FIG. 7, the width of each of the first terminals 16 of the rigid board 10 is approximately 0.35 mm, and the distance between adjacent terminals is approximately 0.15 mm. Also, the width (maximum value) of each of the second terminals 25 of the flexible board 20 is approximately 0.2 mm, and the distance (minimum value) between adjacent terminals is approximately 0.3 mm.

Therefore, the pitch of the first terminals 16 and the second terminals 25 is approximately 0.5 mm. The pitch of the first terminals 16 and the second terminals 25 can be reduced to approximately 0.3 mm. According to the present embodiment, as a result of suppressing the formation of a solder bridge, the distance between adjacent terminals is reduced and the terminals can be arranged at a fine pitch, and therefore, high integration of the printed circuit board (composite module) can be achieved.

In the above embodiment, a case was described in which the first printed circuit board is a rigid board and the second printed circuit board is a flexible board, but the invention is not limited to the embodiment described above. For example, the first printed circuit board may be a flexible board, or the second printed circuit board may be a rigid board. In this way, many modifications can be made within the technical idea of the invention by a person having ordinary skill in the art.

The entire disclosure of Japanese Patent Application No.2016-118528, filed Jun. 15, 2016 is expressly incorporated by reference herein.

What is claimed is:

1. A manufacturing method of a printed circuit board, comprising:
(a) preparing first printed circuit board and second printed circuit board, the first printed circuit board being provided with a plurality of first terminals, the second printed circuit board being provided with a plurality of second terminals, and at least one of the plurality of first terminals and the plurality of second terminals being coated with respective solders; and
(b) electrically connecting the plurality of first terminals to the plurality of second terminals, respectively, via the respective solder by heating connecting portions of the first printed circuit board and the second printed circuit board to a temperature that is greater than or equal to a melting point of the solder and applying pressure to the connecting portions,
wherein the plurality of second terminals are arranged along a short axis direction of the second terminals,
each of the plurality of second terminals includes a first end portion and a second end portion in a long axis direction of the second terminal, and
in the step (b), pressure is applied to each second terminal such that the height of each of the first end portion and second end portion is larger than the height in another portion of the second terminal.

2. The manufacturing method according to claim 1, wherein the step (b) includes bringing a thermocompression tool into contact with a predetermined region, of the second printed circuit board, that is located between the first end portions and the second end portions of the plurality of second terminals in plan view.

3. The manufacturing method according to claim 1, wherein the first printed circuit board is a rigid board, and the second printed circuit board is a flexible board.

4. A printed circuit board, comprising:
a first printed circuit board provided with a plurality of first terminals;
a second printed circuit board provided with a plurality of second terminals; and
solders that electrically connect the plurality of first terminals to the plurality of second terminals, respectively,
wherein the plurality of second terminals are arranged along a short axis direction of the second terminals,
each of the plurality of second terminals includes a first end portion and a second end portion in a long axis direction of the second terminal, and
the height of each of the first end portion and second end portion is larger than the height in another portion of each second terminal.

5. The printed circuit board according to claim 4, wherein the plurality of first terminals and the plurality of second terminals are arranged in a pitch that is less than or equal to 0.5 mm.
